(19) United States
(12) Patent Application Publication
(10) Pub. No.: US 2025/0374615 A1
(43) Pub. Date: Dec. 4, 2025

(54) EDGE TERMINATION STRUCTURE

(71) Applicant: NEXPERIA B.V., Nijmegen (NL)

(72) Inventors: Andrew Shaw, Manchester (GB); Ankit Kumar, Manchester (GB); Epameinondas Efthymiou, Manchester (GB); Hungjin Kim, Shanghai (CN)

(73) Assignee: NEXPERIA B.V., Nijmegen (NL)

(21) Appl. No.: 19/222,018

(22) Filed: May 29, 2025

(30) Foreign Application Priority Data
May 29, 2024 (EP) 24178954.4

(51) Int. Cl. H10D 62/10; H10D 64/27

(52) U.S. Cl. CPC H10D 62/102; H10D 64/513

(57) ABSTRACT

The present disclosure relates to an edge termination structure suitable for the MOSFET transistor especially in power applications. An edge termination structure, suitable for the MOSFET transistor, including a plurality of parallel strips and at least one a shield oxide filled trench (SOTR), and the SOTR is perpendicular to the strips and connects with the strips at the end portion of the strips.

### CROSS-REFERENCE TO RELATED APPLICATIONS

This application claims the benefit under 35 U.S.C. § 119(a) of European Patent Application No. 24178954.4 filed May 29, 2024, the contents of which are incorporated by reference herein in their entirety.

### BACKGROUND

### 1. Field of the Disclosure

The present disclosure relates to an edge termination structure suitable for the MOSFET transistor especially in power applications.

### 2. Description of the Related Art

U.S. Pat. No. 9,680,003B2 has a solution where a recess is formed at a semiconductor layer of a device to define a plurality of mesas. An active trench portion of the recess residing between adjacent mesas. A termination portion of the trench residing between the end of each mesa and a perimeter of the recess. The transverse spacing between the mesas and the lateral spacing between the mesas and an outer perimeter of a recess forming the mesas are substantially the same. A shield structure within the trench extends from the region between the mesas to the region between the ends of the mesas and the outer perimeter of the recess forming the mesas. A contact resides between a shield electrode terminal and the shield portion residing in the trench.

U.S. Pat. No. 8,889,511B2 has a method includes forming a shield dielectric layer in a trench in a semiconductor substrate, forming a shield electrode on at least a portion of the shield dielectric layer, and etching the shield dielectric layer so that a portion of the shield dielectric layer is recessed in the trench. The method can include forming a gate dielectric layer on the recessed portion of the shield dielectric layer in the trench, forming a first conductive gate electrode on a first side of the shield electrode and insulated from a first sidewall of the trench by the gate dielectric layer, and forming a second conductive gate electrode on a second side of the shield electrode and insulated from a second sidewall of the trench by the gate dielectric layer.

Accordingly, it is a goal of the present disclosure to provide an improved edge termination structure which provides high area efficiency of the edge termination structure that can enlarge active area and thus improve the current capacity for a given chip area. Manufacturing process of said structure is a cost-effective process as it will reduce one mask used in termination process.

### SUMMARY

According to an example of the disclosure, an edge termination structure, suitable for the MOSFET transistor, comprising a plurality of parallel strips and at least one a shield oxide filled trench, SOTR, wherein the SOTR is perpendicular to the strips and connects with the stripes at the end portion of the stripes.

Preferably, there is at least one dummy trench, which is, at least in one part, parallel to the SOTR.

Preferably, one of the SOTR 6 forms the end of the strips.

Preferably, one SOTR is near the end of the stripes, preferably the SOTR is at most 1 μm from the end portion of the stripes.

Preferably, there are two of the SOTR parallel to each other, preferably the distance between the SOTR 6 is defined as 1-2 mesa pitches—the distance between the main strip 1

Preferably, each of the SOTR consists of shield oxide.

Preferably, a depth of each of the SOTR is the same as a depth of the stripes.

Preferably, a width of each of the SOTR is within a range of 30-70% of the width of the strip.

### BRIEF DESCRIPTION OF THE DRAWINGS

The disclosure will now be discussed with reference to the drawings, which show in:

FIG. 1 shows a prior art solution of an edge termination structure.

FIG. 2 shows an edge termination structure according to the disclosure.

FIG. 3 shows a cross-sections of parts of the edge termination structure according to the disclosure.

FIG. 4 shows a first exemplary embodiment of the edge termination structure according to the disclosure.

FIG. 5 shows a second exemplary embodiment of the edge termination structure according to the disclosure.

FIG. 6 shows a third exemplary embodiment of the edge termination structure according to the disclosure.

### DETAILED DESCRIPTION

For a proper understanding of the disclosure, in the detailed description below corresponding elements or parts of the disclosure will be denoted with identical reference numerals in the drawings.

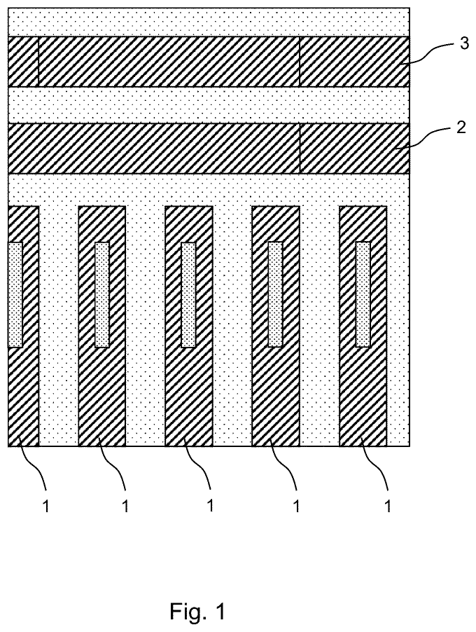

FIG. 1 shows a solution known from the prior art. Near the end of the strips 1 there is a grounded trench 2 behind which there is a dummy trench 3, which is not connected, galvanically, to any electrical potential and thus its electrical potential varies. In such a structure two parameters are important—size of a mesa, that is a distance between strips 1, and a size of a gap, that is a distance between strips 1 and the grounded trench 2.

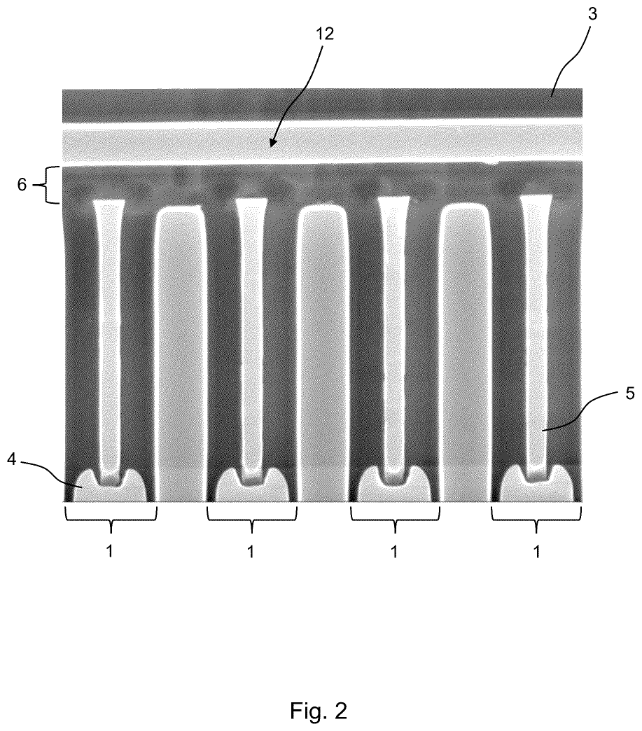

In an edge termination structure according to the disclosure there is a plurality of parallel strips 1 which are connected with at least one shield oxide filled trench, SOTR, 6, which is perpendicular to the strips 1. In such a case, as shown in FIG. 2, there is only one parameter which needs to be considered, that is a width of the SOTR 6. Other parts of the strips 1 are also visible—there is visible a gate poly top 4, a shield poly top 5 and shield oxide 8.

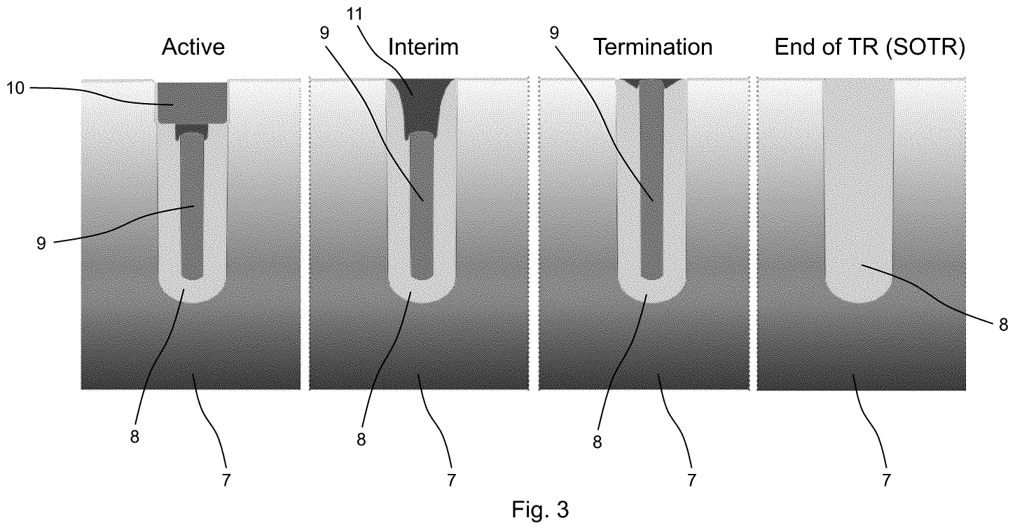

In FIG. 3 a cross-section of each part of the edge termination structure is visible. An active cross-section is the most bottom part of the strips 1 as shown in FIG. 2 In the substrate 7 the strip 1 is form by a shield oxide 8 in which a shield poly 9 is located on top of which a gate poly 10 is located. An interim part of the strip 1 is located further to toward the end portion 12 of the strip 1. As previously the strip 1 is form by the shield oxide 8 in which the shield poly 9 is located but in this section a HDP oxide 11 is on top of it. A termination portion is located at the end portion 12 of the strip 1 where previously the strip 1 is form by the shield oxide 8 in which the shield poly 9 is located such that it reaches the top part of the strip 1. The SOTR 6 is made as the shield oxide 8 only. It should be noted that in this example SOTR 6 have the same depth as stripe 1. a width of each of the SOTR 6 is within a range of 30-70% of the width of the strip (1). In presented embodiment the SOTR 6 width is within a range of 0.4-1.1 μm.

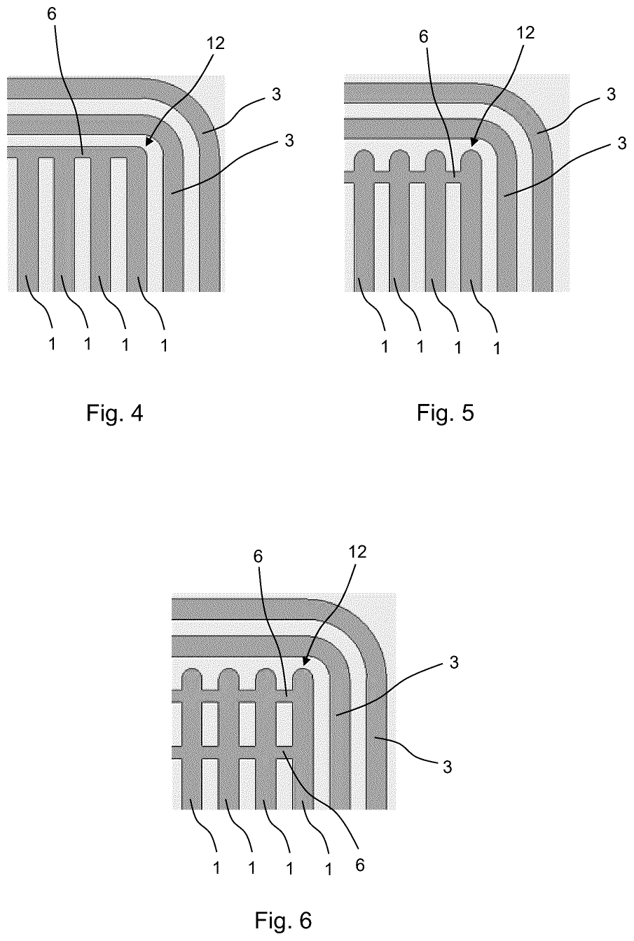

FIGS. 4-6 shows exemplary embodiments of the present disclosure. In FIG. 4 the SOTR 6 is located at the end portion 12 of the strip 1 and there is only one SOTR 6 in this embodiment. Near the strips 1 and SOTR 6 the dummy trench 3 is placed, which is optional—the dummy trenches 3, in general, are used for process uniformity. In this example there are two dummy trenches 3. The dummy trench 3 is, at least in one part, parallel to the SOTR 6. On FIG. 5 the SOTR 6 is placed near the end portion 12 of the strip 1, but not at the end—preferably at most 1 μm from the end portion 12 of the strip 1, even more preferably at the end portion 12 of the strip 1. In such a case it should be noted that the SOTR 6 width should be calculated here as if it is wider since the protruding end portions 12 of the strips 1 act as wideners of the SOTR 6. In FIG. 6 there are two SOTR 6—one is placed as in FIG. 5, and other one is placed further away from the end portions 12 of the strips 1. Both SOTR 6 are parallel in this exemplary embodiment and a distance between them is, in this embodiment, 1.5 -μm, however this dimension may be design such that the distance between the SOTR 6 is smaller or greater. In such a case the edge termination structure is more robust due to the additional SOTR 6 in the design. Preferably the distance between the SOTR 6 is defined as 1-2 mesa pitches—the distance between the main strip 1.

### LIST OF REFERENCE NUMERALS USED

1 strip
2 grounded trench
3 dummy trench
4 gate poly top
5 shield poly top
6 shield oxide filled trench, SOTR
7 substrate
8 shield oxide
9 shield poly
10 gate poly
11 HDP oxide
12 end portion of the strip

1. An edge termination structure, for a MOSFET transistor, comprising: a plurality of parallel strips and at least one shield oxide filled trench (SOTR), wherein the SOTR is perpendicular to the strips and connects with the strips at an end portion thereof.

2. The edge termination structure according to claim 1, wherein there is at least one dummy trench, which is at least in one part, parallel to the SOTR.

3. The edge termination structure according to claim 1, wherein one of the SOTR forms the end of the strips.

4. The edge termination structure according to claim 1, wherein one SOTR is near the end of the strips.

5. The edge termination structure according to claim 3, wherein there are two of the SOTRs that are parallel to each other, and a distance between the SOTRs is μm defined as 1-2 mesa pitches.

6. The edge termination structure according to claim 1, wherein each SOTR consists of shield oxide.

7. The edge termination structure according to claim 1, wherein each SOTR has a depth that is the same as a depth of the strips.

8. The edge termination structure according to claim 2, wherein one of the SOTRs forms the end of the strips.

9. The edge termination structure according to claim 2, wherein one SOTR is at most 1 μm from the end portion of the stripes.

10. The edge termination structure according to claim 4, wherein there are two of the SOTRs that are parallel to each other, and a distance between the SOTRs is μm defined as 1-2 mesa pitches.

11. The edge termination structure according to claim 4, wherein each SOTR consists of shield oxide.

12. The edge termination structure according to claim 4, wherein each SOTR has a depth that is the same as a depth of the strips.

13. The edge termination structure according to claim 4, wherein each SOTR has a width that is within a range of 30-70% of the width of the strip.

14. The edge termination structure according to claim 5, wherein there are two of the SOTRs that are parallel to each other, and a distance between the SOTRs is μm defined as 1-2 mesa pitches.

15. The edge termination structure according to claim 5, wherein each SOTR consists of shield oxide.

16. The edge termination structure according to claim 5, wherein each SOTR has a depth that is the same as a depth of the strips.

17. The edge termination structure according to claim 5, wherein each SOTR has a width that is within a range of 30-70% of the width of the strip.
